(19) United States
(12) Patent Application Publication
(10) Pub. No.: US 2022/0229943 A1
(43) Pub. Date: Jul. 21, 2022

(54) JOINT RETRIEVAL AND MESH DEFORMATION

(71) Applicant: ADOBE INC., San Jose, CA (US)

(72) Inventors: Mikaela Angelina UY, Stanford, CA (US); Vladimir KIM, Seattle, WA (US); Minhyuk SUNG, Cupertino, CA (US); Noam AIGERMAN, San Francisco, CA (US); Siddhartha CHAUDHURI, Karnataka (IN)

(21) Appl. No.: 17/153,380

(22) Filed: Jan. 20, 2021

(51) Int. Cl. G06F 30/10; G06N 3/08; G06T 19/20

(52) U.S. Cl. CPC G06F 30/10; G06T 2219/2021; G06T 19/20; G06N 3/08

(57) ABSTRACT

Embodiments provide systems, methods, and computer storage media for generating a 3D model from a target 2D image or 3D point cloud (e.g., generated by a 3D scan). Given a particular target, a retrieval network retrieves or identifies a source model from a database, and a deformation network deforms the source model to fit the target. In some cases, joint learning is employed to enable the retrieval and deformation networks to jointly learn a deformation-aware retrieval embedding space and an individualized deformation space for each source model. In some cases, the retrieval network retrieves based on distance in the deformation-aware retrieval embedding space, enabling the retrieval module to retrieve a source model that best fits to the target after deformation. In some cases, a deformation is decomposed into a plurality of per-part deformations, and/or and the retrieval embedding space is used to select training data.

### BACKGROUND

A three-dimensional (3D) model can digitally represent an object or a collection of objects with a set of 3D points connected by lines, triangles, surfaces, or other means. 3D models are useful in a variety of fields such as film, animation, gaming, engineering, industrial design, architecture, stage and set design, and others. Sometimes, a 3D artist, designer, or other person will want to create a 3D model that digitally represents a particular reference object represented in an image or a 3D scan. One option to accomplish this is to create the 3D model manually. However, creating high-quality 3D models from a reference image or a scan is a laborious task, requiring significant expertise in 3D sculpting, meshing, and texturing. In some cases, creating suitable 3D models is beyond the skill of the person who wants the model. There are also some automated techniques for generating 3D models from a reference image or scan. However, current automated techniques cannot produce the fidelity, level of detail, and overall quality of 3D models generated by professional 3D artists.

### SUMMARY

Embodiments of the present invention are directed to generating a 3D model from a target 2D image or 3D point cloud (e.g., generated by a 3D scan). Given a particular target, a retrieval network retrieves or identifies a source model from a database of source models, and a deformation network deforms the identified source model to fit the target. In some embodiments, this retrieve-and-deform technique is implemented using a deformation network, which allows the retrieve-and-deform technique to use a natural image or a scan as an input. In some cases, a deformation is decomposed into separate deformations of each individual part of a source model, and the deformation network is used to predict the deformations to the individual parts, enabling the use of existing collections of heterogeneous shapes with various structural variations. In some embodiments, a retrieval network and a deformation network are jointly trained in a joint training process to jointly learn a retrieval embedding space and an individual deformation space for each source model in a database, which encourages the deformation network to learn to predict deformations that are more suitable for the shapes retrieved by the retrieval network. As such, various implementations of the present techniques can generate 3D models that match a target image or scan better than in prior techniques.

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

### BRIEF DESCRIPTION OF THE DRAWINGS

The present invention is described in detail below with reference to the attached drawing figures, wherein:

FIG. 1 is a block diagram of an example computing system suitable for generating a 3D model, in accordance with embodiments of the present invention;

FIG. 2 is a data flow diagram illustrating an example retrieval module, in accordance with embodiments of the present invention;

FIG. 3 is a data flow diagram illustrating an example deformation module, in accordance with embodiments of the present invention;

FIG. 4 is a flow diagram showing a method for generating a 3D model that approximates a target shape, in accordance with embodiments of the present invention;

FIG. 5 is a flow diagram showing a method for generating a 3D model that approximates a target shape by applying per-part deformations, in accordance with embodiments of the present invention; and

FIG. 6 is a block diagram of an example computing environment suitable for use in implementing embodiments of the present invention.

### DETAILED DESCRIPTION

### OVERVIEW

Some existing techniques attempt to automatically generate a 3D model from a reference (or target) object. One such technique is surface reconstruction, which attempts to infer a surface representation of a coarse input (e.g., coarse point cloud). Examples of existing surface reconstruction techniques include AtlasNet, DeepSDF, OccupancyNet, and variants thereof. However, existing surface reconstruction techniques often produce reconstructions that look coarse and blobby and exhibit various artifacts and, as a result, cannot reliably create high-quality assets with the fidelity, level of detail, and overall quality that is often needed.

Another technique involves learning latent representations for 3D shapes in a retrieval embedding space, encoding a database of 3D models into the retrieval embedding space, and retrieving the 3D model that has a 3D shape that is closest to the 3D shape of a target. To encode a target shape, some techniques have used two-dimensional (2D) convolutional neural networks (CNNs) or shape encoders to encode a shape from some partial observation, such as a natural image or a point scan. To represent shape geometry for 3D models, 3D shape has been modeled with implicit functions, atlases, volumetric grids, point clouds, and/or meshes. However, these models tend to under-perform on complex shapes with intricate part structures. A simple shape retrieval could also be viewed as the simplest version of such a shape generator, where the system simply returns the nearest neighbor in the latent space. Although simple shape retrieval may result in a stock-quality model, unless the relevant database contains all possible objects, simple shape retrieval often fails to produce a good fit for an encoded target.

Some techniques seek to address this concern by additionally deforming a retrieved shape to fit a desired target. One approach is to exhaustively deform all shapes in a database to the target and select the best fit, but this approach is computationally and often prohibitively expensive. Some recent techniques have proposed directly retrieving a high-quality 3D model from a database and deforming it to match a target image or point cloud, thereby approximating the target shape while preserving the quality of the original source model. These prior techniques largely focus on one of two complementary subproblems: either retrieving an appropriate mesh from a database or training a neural network to deform a source to a target. In most cases, the static database mesh most closely matching the target is retrieved, and then deformed for a better fit. In most cases, however, this retrieval step is independent of the subsequent deformation procedure. As a result, most conventional techniques ignore the possibility that a database shape with different global geometry nevertheless possess local details that will produce the best match after deformation. For example, consider an example where the target (T) is a wide bench with armrests and two potential sources are: (S1) a wide bench without armrests and (S2) a short bench with armrests. S1 might be geometrically closest to T, but if a deformation module is capable of widening S2, S2 may be the better source to be retrieved for T. Accordingly, conventional techniques that fail to consider the best match after deformation can fail to produce a good fit for an encoded target.

Only a few works explicitly consider deformation-aware retrieval. For example, one such technique introduces a deep embedding that first retrieves a shape from a database, and then separately deforms the retrieved shape to the target by directly optimizing As-rigid-as-possible Deformation (ARAP) loss. However, this choice limits targets to be full shapes, as direct optimization is not possible with natural images or partial scans with occluded parts. As such, prior deformation-aware retrieval techniques such as this are not capable of automatically generating a 3D model from a target image or scan. Furthermore, in existing deformation-aware retrieval techniques, the deformation process is a fixed, non-trainable black box, cannot operate on a database of heterogeneous shape structures, may necessitate time-consuming, manually-specified optimization of a fitting energy, exhaustive enumeration of deformed variants, and does not support back-propagating gradients in order to directly translate deformation error to retrieval error. As such, prior deformation-aware retrieval techniques have a variety of limitations that may not be suitable for automatically generating a 3D model from a target image or scan.

With respect to conventional deformation techniques, a number of conventional techniques consider how to deform a source 3D model to a target. When the target is a full shape, direct optimization can be used. However, if the target is a different modality such as an image or partial scan, conventional techniques employ a corresponding deformation prior. Some neural techniques have been used to learn such deformation priors from collections of shapes, representing deformations as volumetric warps, cage deformations, or vertex-based offsets. To make learning easier, these techniques typically assume homogeneity in the sources and represent the deformation with the same number of parameters for each source (e.g., grid control points, cage mesh, or number of vertices). However, these assumptions make them less suitable for databases of heterogeneous shape structures with significant structural variations at the part level. Since most existing databases of 3D models have significant structural variations at the part level, using conventional deformation procedures to learn from existing databases of 3D models typically ignores part-level detail and therefore can fail to produce a good fit for certain targets.

Accordingly, embodiments of the present invention are directed to techniques for generating a 3D model from a target object represented by a 2D image or a 3D point cloud (e.g., generated by a 3D scan). In an example embodiment, a target image or point cloud is encoded, an existing 3D model is retrieved from a database of 3D models based on proximity to the target, and the retrieved 3D model is used as a source model and deformed to match the target. In some embodiments, this retrieve-and-deform technique is implemented using a deformation network, which allows the retrieve-and-deform technique to use a natural image or a scan as an input. In some cases, a deformation is decomposed into separate deformations of each individual part of a source model, and the deformation network is used to predict the deformations to the individual parts of the source model, enabling the use of existing collections of heterogeneous shapes with various structural variations. In some embodiments, a retrieval network and a deformation network are jointly trained in a joint training process to jointly learn a retrieval embedding space and an individual deformation space for each source model in a database, which encourages the deformation network to learn to predict deformations that are more suitable for the shapes retrieved by the retrieval network. As such, various implementations of the present techniques can generate 3D models that match a target image or scan better than in prior techniques.

Unlike prior techniques that independently focus on either shape retrieval or deformation, some embodiments employ a joint learning procedure that alternately trains a deformation network and a retrieval network to jointly learn a retrieval embedding space and a deformation space represented by learnable, source-dependent deformation functions. This joint learning procedure enables the retrieval network to learn a deformation-aware retrieval embedding space and the deformation network to learn a retrieval-aware deformation space. Learning a deformation-aware retrieval embedding space enables the retrieval network to learn to retrieve 3D models that are more amenable to match a target after an appropriate deformation. Learning a retrieval-aware deformation space enables the deformation network to learn to fit shapes of the types of 3D models retrieved by the retrieval network to target shapes. As such, in some embodiments, the retrieval network is optimized to retrieve sources that the deformation network can fit well to an input target. Additionally or alternatively, the retrieval embedding space is used to select source models to train the deformation network, enabling the deformation network to invest and optimize its learning capacity to learn meaningful deformations between meaningful shape pairs. As such, in various embodiments, this joint learning procedure is used to train the retrieval and deformation networks to generate 3D models that match a target image or scan better than in prior techniques.

In some embodiments, a deformation is decomposed into a plurality of per-part deformations, the deformation network predicts a deformation for each part of a source model (e.g., a retrieved source model), and/or each part of the source model is deformed accordingly to generate a deformed 3D model that reproduces, matches, or approximates a target shape. In some cases, the deformation network is used to compose a differentiable, part-aware deformation function by predicting deformation parameters for separate deformations of individual parts of a 3D model. In an example implementation, each 3D source model in a database is segmented into constituent parts, and corresponding per-part axis-aligned bounding boxes are generated or obtained. In some embodiments, the deformation network learns an individual deformation space for each source model. In an example implementation, the individual deformation space for each source model is represented by a learnable global code representing global features of the source model, a set of learnable local codes representing local features for each part of the source model, and/or a learnable scaler representing the range of deformability of the source model.

At query time, one of the 3D models is retrieved and decomposed into its constituent parts, and the deformation network is used to predict one or more values representing a translation and/or resizing of the bounding box for each part. The predicted deformation parameters for each part are used to deform each part by applying a corresponding deformation to the part's bounding box. As a result, in some embodiments, the deformation network effectively learns a source-specific deformation function that depends on the number of parts in a 3D source. In this example, since the source-specific deformation functions accommodate varying numbers of parts and structural relationships, the deformation network has the capability of handling heterogeneous collections, such as heterogeneous collections of shapes that appear “in the wild,” which often vary in their part structure and geometry and conventionally require different deformation spaces for different source models. Furthermore, the deformation network in this example does not require part labels or consistent segmentations, can work regardless of part count, can work with automatically-segmented meshes, and can even handle multiple differently segmented instances of the same source shape.

Implementing a neural deformation in a retrieve-and-deform pipeline is non-trivial. Existing datasets may include partial and ground truth representations of some target object, but there is usually no ground truth or optimal source model to learn from. Furthermore, deformability is not a binary relationship, but rather a range of how well a deformed model fits a particular source. As a result, there is no obvious way to select an ideal or ground truth source model. Previous techniques simply sample a set of sources for a particular target randomly, and train and test on random source-target pairs, which is not ideal. Moreover, with a selected source model, there is usually no ground truth or optimal deformation parameters to fit the source model to a particular target, which can result in semantically implausible shapes or bad fitting. Finally, if there is a bad fitting error, there is usually no way to know whether it is caused by a bad retrieval or a bad deformation.

To address this, in some embodiments, a biased selection procedure is used to select an input source model to use with a paired input target and ground truth deformed model from a training dataset, and the selected input source model is used with the ground truth deformed model to train the deformation network and/or the retrieval network. In an example implementation, the retrieval network is trained to learn a retrieval embedding space with a distance that is proportional to post-deformation fitting losses, and shapes with low fitting errors are represented nearby in the retrieval embedding space. Then, a source model is probabilistically sampled for a particular target using a probability that is weighted by distance between the source and target in the retrieval embedding space. As such, in this example, the deformation network is trained with a bias towards high probability source models and not random ones, ensuring the deformation network is aware of the retrieval network, and expanding the deformation network's capacity to learn to generate meaningful matches to a target shape.

As such, using certain implementations described herein, even amateur users can easily generate a high quality 3D model from a target image or scan. Depending on the implementation, a retrieval-and-deformation procedure is applied, a deformation network is used to deform a source model, and/or a deformation is decomposed into a plurality of per-part deformations. In some cases, joint learning is employed to enable retrieval and deformation networks to learn from one another, and/or a learned retrieval embedding space is used to select better training data to train the deformation network. As such, using various implementations described herein, higher quality 3D models are generated to match a target better than prior techniques.

### EXAMPLE 3D MODEL GENERATION ENVIRONMENT

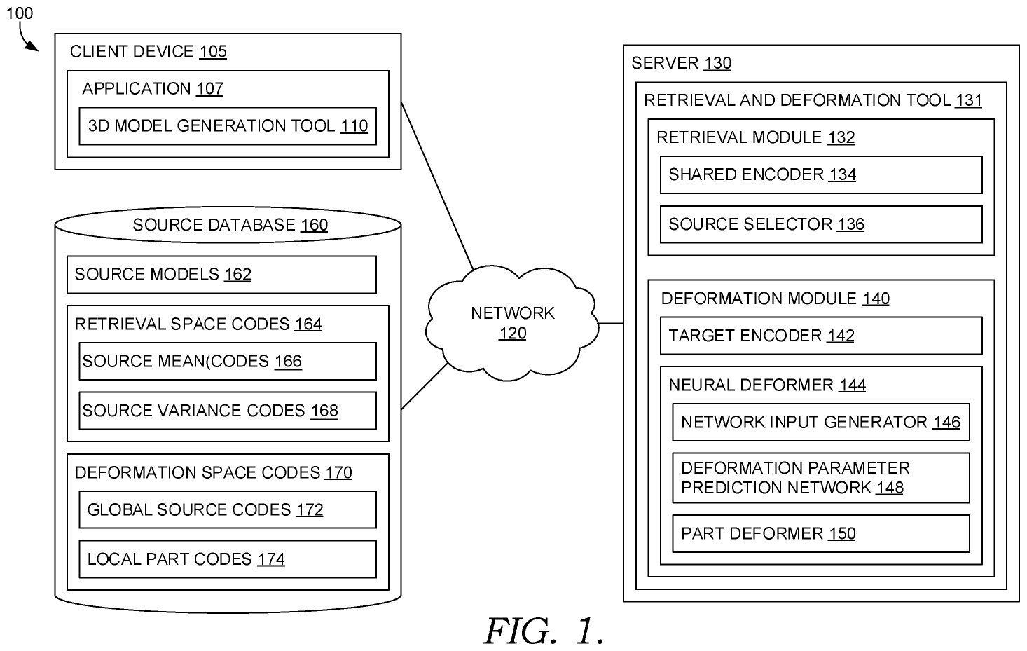

Referring now to FIG. 1, a block diagram of example environment 100 suitable for use in implementing embodiments of the invention is shown. Generally, environment 100 is suitable for generating a 3D model, and, among other things, facilitates generating a 3D model from a target shape. At a high level, environment 100 includes client device 105, server 130, and source database 160.

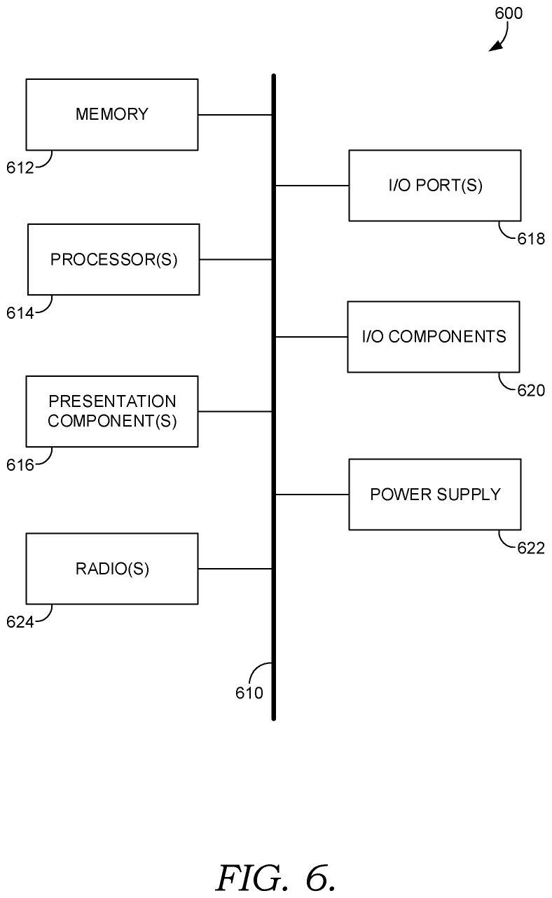

Depending on the implementation, client device 105 and/or server 130 are any kind of computing device capable of facilitating 3D model generation. For example, in an embodiment, client device 105 and/or server 130 are each a computing device such as computing device 600 of FIG. 6. In some embodiments, client device 105 and/or server 130 are a personal computer (PC), a laptop computer, a mobile or mobile device, a smartphone, a tablet computer, a smart watch, a wearable computer, a personal digital assistant (PDA), a music player or an MP3 player, a global positioning system (GPS) or device, a video player, a handheld communications device, a gaming device or system, an entertainment system, a vehicle computer system, an embedded system controller, a camera, a remote control, a bar code scanner, a computerized measuring device, an appliance, a consumer electronic device, a workstation, or any combination of these delineated devices, or any other suitable computer device.

In various implementations, the components of environment 100 include computer storage media that stores information including data, data structures, computer instructions (e.g., software program instructions, routines, or services), and/or models (e.g., 3D models, machine learning models) used in some embodiments of the technologies described herein. For example, in some implementations, source database 160 comprises a data store (or computer data memory). Further, although depicted as a single data store component, in some embodiments, source database 160 is embodied as one or more data stores (e.g., a distributed storage network) and/or is implemented in the cloud. Similarly, in some embodiments, client device 105 and/or server 130 comprise one or more corresponding data stores, and/or are implemented using cloud storage.

In the example illustrated in FIG. 1, the components of environment 100 communicate with each other via network 120. In some non-limiting example implementations, network 120 includes one or more local area networks (LANs) and/or wide area networks (WANs). Such networking environments are commonplace in offices, enterprise-wide computer networks, intranets, and the Internet.

In the example illustrated in FIG. 1, client device 105 includes application 107 with 3D model generation tool 110, and server 130 includes retrieval and deformation tool 131. In some embodiments, 3D model generation tool 110, retrieval and deformation tool 131, and/or any of the elements illustrated in FIG. 1 are incorporated, or integrated, into an application(s), or an add-on(s) or plug-in(s) to an application(s). In some embodiments, the application(s) is a stand-alone application, a mobile application, a web application, or the like. For example, in some implementations, the application(s) comprises a web application that runs in a web browser and/or is hosted at least partially server-side. In some cases, the application is integrated into an operating system (e.g., as a service). Although some embodiments are described with respect to an application(s), some implementations additionally or alternatively integrate any of the functionality described herein into an operating system (e.g., as a service), a server (e.g., a remote server), a distributed computing environment (e.g., as a cloud service), and/or otherwise.

Depending on the embodiment, various allocations of functionality are implemented across any number and/or type(s) of devices. In the example illustrated in FIG. 1, 3D model generation tool 110 and retrieval and deformation tool 131 coordinate via network 120 to execute the functionality described herein. In another example, 3D model generation tool 110 and retrieval and deformation tool 131 (or some portion thereof) are integrated into a common application executable on a single device. In yet another example, 3D model generation tool 110 and retrieval and deformation tool 131 (or some portion thereof) are distributed across some other number and/or type(s) of devices. These are just examples, and any suitable allocation of functionality among these or other devices is possible within the scope of the present disclosure.

To begin with a high-level overview of an example workflow through the configuration illustrated in FIG. 1, assume a user operating client device 105 wants to generate a 3D model from a reference object. In some embodiments, the reference object is represented by a 2D image, and the user wants to generate a 3D model that reproduces, matches, and/or approximates the shape and/or proportions of an object in the image. Accordingly, in some embodiments, 3D model generation tool 110 provides an interface that allows the user to upload or otherwise designate the image, 3D model generation tool 110 sends the image to retrieval and deformation tool 131, and retrieval and deformation tool 131 uses the image as a target to generate a corresponding 3D model that reproduces, matches, and/or approximates the shape of the object in the image. In this example, retrieval and deformation tool 131 sends the generated 3D model to 3D model generation tool 110, which makes the generated 3D model available to the user via client device 105.

In another example embodiment, the user operates a 3D scanner (e.g., a laser scanner or Digital Aerial Photogrammetry (DAP) scanner) to generate, or otherwise obtains, a 3D representation of a physical object, such as a 3D point cloud or 3D model. However, in some cases, the best 3D representation available is noisy, partial, or otherwise incomplete. Therefore, in some cases, assume the user wants to generate a more complete 3D model that reproduces, matches, and/or approximates the shape and/or proportions of the available 3D representation. Accordingly, in some embodiments, 3D model generation tool 110 provides an interface that allows the user to upload or otherwise designate the existing 3D representation, and 3D model generation tool 110 sends the 3D representation to retrieval and deformation tool 131. In some embodiments, where the 3D representation includes a 3D model, the 3D model is sampled to generate a 3D point cloud, whether on client device 105 or server 130. As such, in some embodiments, retrieval and deformation tool 131 uses a 3D point cloud as a target to generate a corresponding 3D model that reproduces, matches, and/or approximates the shape of the object represented by the 3D point cloud. In this example, retrieval and deformation tool 131 sends the generated 3D model to 3D model generation tool 110, which makes the generated 3D model available to the user via client device 105.

At a high level, retrieval and deformation tool 131 accepts a representation of a target shape, retrieves a source model from source model database 160, and deforms the source model to reproduce, match, and/or approximate the target shape. Before describing retrieval and deformation tool 131, some example embodiments of source model database 160 will now be described.

Source model database 160 includes a collection of source models 162. Depending on the embodiment, source models 162 include any type of 3D model such as 3D meshes, computer-aided design (CAD) models, and/or others. In an example embodiment, each of the source models 162 is a parametric model that represents each part with a corresponding axis-aligned bounding box, and/or source models 162 have different numbers of parts and/or parametric handles. In some cases, an existing collection of 3D models with per-part axis-aligned bounding boxes is used. In other cases, a collection of 3D models is generated and/or processed to create source models 162. In an example embodiment where an existing collection of 3D models has not previously been segmented into parts, manual and/or automatic part segmentation is applied to the 3D models using any known technique (e.g., PartNet), and an axis-aligned bounding box is generated for each part. In another example where an existing collection of 3D models is segmented into small parts with fine detail, some connected part are grouped together into bigger parts (e.g., to facilitate faster learning and/or inference). By generating a representation of multiple parts of source models 162, a deformation of a particular model may be parameterized into a deformation for each part in the model (e.g., by translating and/or resizing a bounding box to control the location and/or size of a corresponding part).

As explained in more detail below, in some embodiments, source models 162 are encoded into and/or otherwise represented in a retrieval embedding space (e.g., via retrieval space codes 164 of FIG. 1). In the example illustrated in FIG. 1, each of the source models 162 is represented by a mean or center location (e.g., source mean codes 166) and a variance (e.g., source variance codes 168) in the retrieval embedding space. Additionally or alternatively, and as explained in more detail below, in some embodiments, the individual deformation space of each of the source models 162 is represented in a deformation space (e.g., deformation space codes 170 of FIG. 1). In the example illustrated in FIG. 1, each of the source models 162 is represented by a corresponding global code (e.g., global source codes 172), and each of a plurality of parts in a source model is represented by a corresponding local code (e.g., local part codes 174).

Returning now to retrieval and deformation tool 131, retrieval and deformation tool 131 includes retrieval module 132 and deformation module 140. Retrieval module 132 accepts a representation of a target shape, and retrieves or otherwise identifies a source model to be retrieved from source model database 160 based on proximity to the target shape in the retrieval embedding space. Deformation module 140 deforms the source model to reproduce, match, and/or approximate the target shape.

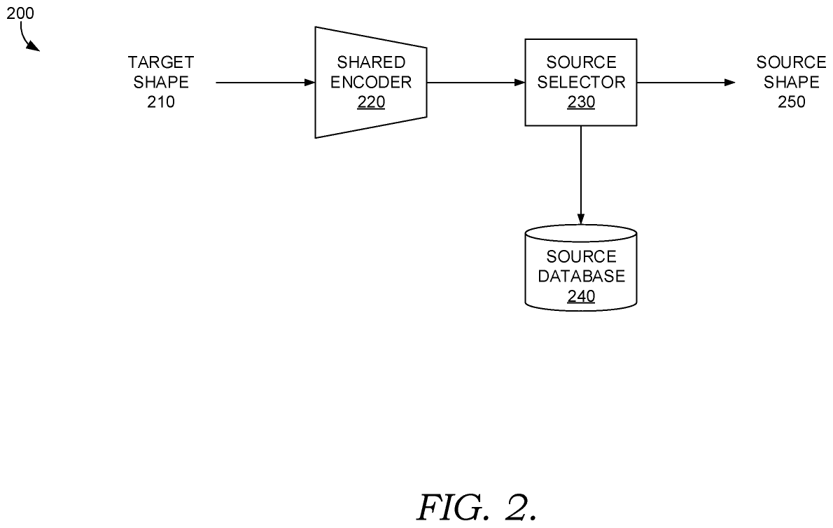

In the example illustrated in FIG. 1, retrieval module 132 includes shared encoder 134 and source selector 136. Shared encoder 134 generates an encoded representation of a target shape, and source selector 136 selects one of the source models 162 from source model database 160 based on proximity in the retrieval embedding space. In an example implementation, source selector 136 computes a distance between the encoded representation of the target shape and a representation of each source model in the retrieval embedding space (e.g., using retrieval space codes 164), and selects the source model that is the smallest distance to the target. FIG. 2 is a data flow diagram illustrating an example retrieval module 200 including shared encoder 220 and source selector 230. In some embodiments, retrieval module 200 and its components correspond with retrieval module 132 of FIG. 1 and its components.

Generally, retrieval module 200 accepts a representation of target shape 210, and shared encoder 220 encodes it into a learned retrieval embedding space. In some embodiments in which the representation of target shape 210 includes a 3D point cloud, shared encoder 220 is implemented using a point cloud encoder (e.g., the encoder from PointNet). In some embodiments in which the representation of target shape 210 includes a 2D image, shared encoder 220 is implemented using an image encoder (e.g., ResNet). As such, shared encoder 220 generates a latent code for a target shape t_{R}=ϵ [symbol] ⁿ₄. In an exmple embodiment, n₄=256.

In some cases, shared encoder 220 is considered shared because it is used to encode both a target (e.g., at query time) and each source model in source database 240 (which corresponds to source database 160 of FIG. 1, in some embodiments) (e.g., prior to query time). In some implementations, each source model in source database 240 is represented by a region in the learned retrieval embedding space, and the region for a given source model is represented by a mean or center code SR ϵ [symbol] ⁿ₄ (e.g., a corresponding one of source mean codes 166) and a variance matrix s_{R}^{v} ϵ [symbol] ⁿ₄ (e.g., a corresponding one of source variance codes 168) that defines an egocentric distance field. In an example embodiment, n₄=256. In some embodiments, each variance matrix is diagonally positive-definite, and positivity is enforced by the sigmoid activation function. In some implementations, shared encoder 220 is used to generate the mean or center codes, and the variance codes are directly optimized during training.

Depending on the implementation, shared encoder 220 is used to generate the mean or center codes for the source models in source database 240 in different ways. For example, in some embodiments in which shared encoder 220 is implemented using a point cloud encoder, for each source model in source database 240, a corresponding 3D point cloud is sampled from the source model, and the 3D point cloud is fed into shared encoder 220 to generate a corresponding mean or center code SR ϵ [symbol] ⁿ₄. In some embodiments in which shared encoder 220 is implemented using an image encoder, for each source model in source database 240, one or more projection images of the source model are generated (e.g., a front-facing projection image, projection images from different perspectives), and each projection image is fed into shared encoder 220 to generate a corresponding mean or center code s_{R} ϵ [symbol] ⁿ₄.

In some embodiments, instead of training an encoder to generate source model variances codes, the variance codes are directly optimized during training. By way of motivation, in some embodiments, a particular source model will be deformed, so rather than representing a single shape (e.g., the shape of the source model) in the retrieval embedding space, each source model is represented by a range of possible deformed shapes in the retrieval embedding space. In an example implementation, this range is represented by a variance that defines an area in the retrieval embedding space, centered around the point where the source gets encoded, and that represents a range of potential deformations of the source model. Accordingly, in some embodiments, a distance function that compares a target to a source model using both the center and variance for a source model serves to define a deformation-aware retrieval. In an example implementation, a distance function is defined as:

d(s,t) [symbol] =\sqrt{( [symbol] - [symbol] )^{T} [symbol] ( [symbol] - [symbol] )} (Eq. 1)

where t_{R} is an encoded target code, s_{R} is an encoded mean or center code for a source model, and s_{R}^{v} is a variance code for the source model.

In an example implementation, shared encoder 220 encodes a representation of target shape 210, source selector 230 uses the distance function to calculate the distance between the encoded target and each source model in source database 240, and source selector 230 selects, retrieves, or otherwise identifies a source model with the shortest computed distance from the target (e.g., source shape 250). The identified source model is deformed to generate a deformed model, as explained in more detail below. Because retrieval module 200 identifies a source model based on proximity in a deformation-aware retrieval embedding space, the retrieval module retrieves a source model that best fits to the target after deformation.

In an example implementation of training, the parameters of shared encoder 220 and the variance codes sR for the source models are optimized for pairs of input targets and corresponding ground truth deformed models. In some embodiments, the variance codes are directly optimized in an auto-decoder fashion, where the learnable parameters—the values of the variance codes—are initialized (e.g., randomly) and optimized during training. As such, each source model is encoded into the retrieval embedding space using learned variance codes that represent the unique deformation space of each source model, rather than simply encoding its geometry, thereby enabling retrieval module 200 to handle source models with similar geometry, but different parameterizations.

As such, and returning to the example illustrated in FIG. 1, retrieval module 132 selects, retrieves, or otherwise identifies from source database 160 a source model with the shortest computed distance from the target. Deformation module 140 accesses the identified source model and deforms it. In FIG. 1, deformation module 140 includes target encoder 142 and neural deformer 144, which includes network input generator 146, deformation parameter prediction network 148, and part deformer 150. At a high level, target encoder 142 generates an encoded representation of the target shape, and neural deformer 144 predicts and executes a deformation for each part of the identified source model. In an example implementation, for each part, network input generator forms a composite representation of the target shape, the source model, and the part, deformation parameter prediction network 148 predicts a representation of a deformation of the part, and part deformer 150 applies the deformation to the part. The process is repeated for each part of the identified source model to obtain a deformed model that reproduces, matches, and/or approximates the shape and/or proportions of the target shape.

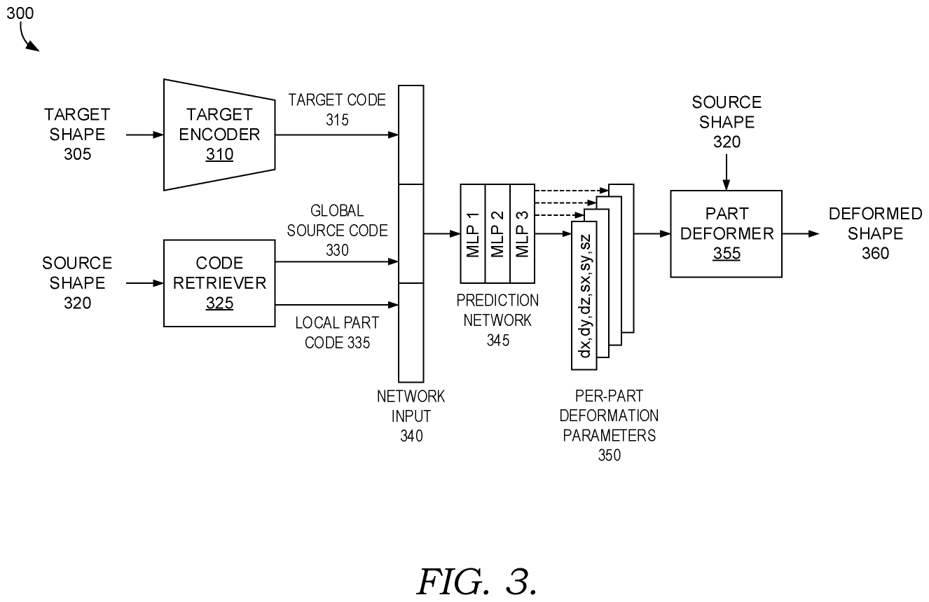

FIG. 3 is a data flow diagram illustrating an example deformation module 300. In some embodiments, deformation module 300 corresponds with deformation module 140 of FIG. 1. In some embodiments, deformation module 300 determines and applies part deformations that vary depending on the source model being deformed. In some cases, deformation module 300 predicts deformation parameters representing a translation and/or an axis-aligned resizing for each part in a source model. In some implementations, since the number of parts for different source models varies, the deformation functions {Dₛ} are source-dependent. In these implementations, deformation module 300 applies a different deformation function Dₛ for each source model s based on its parts.

To facilitate per-part deformations, in some embodiments, each source model and each of its parts are represented in a deformation space. In an example embodiment, each source model is assigned a global code s_{D}^{glob} ϵ [symbol] ⁿ₁ (e.g., global source codes 172 of FIG. 1), and each of its parts is assigned a local code s_{D}^{i=1...N}^{ₛ}ϵ [symbol] ⁿ^{₂} (e.g., local part codes 174 of FIG. 1). In an example embodiment, n₁=256 and n₂=32. In some implementations, the global codes for the source models and local codes for their parts are directly optimized during training to minimize post-deformation fitting loss. As such, the individual deformation space of each of the source models 162 is represented in a deformation space using learned global codes for the source models and local codes for their parts.

In some embodiments, deformation module 300 predicts and applies a deformation for each part in a source model based on a composite representation of a target shape, the source model, and the part. In the example illustrated in FIG. 3, deformation module 300 includes target encoder 310, code retriever 325 prediction network 345, and part deformer 355.

Generally, target encoder 310 accepts a representation of target shape 305 and encodes it into target code 315 in a learned deformation space. In some embodiments in which the representation of target shape 305 includes a 3D point cloud, target encoder 310 is implemented using a point cloud encoder (e.g., the encoder from PointNet). In some embodiments in which the representation of target shape 305 includes 2D image, target encoder 310 is implemented using an image encoder (e.g., ResNet). As such, target encoder 310 generates target code 315 t_{D}=ED(t) ϵ [symbol] ⁿ^{₃} for a given target shape 305. In an example implementation, n₃ =256.

In an example implementation, for each part of an identified source model, code retriever 325 generates a corresponding network input 340. In some embodiments, code retriever 325 receives a representation of a source model (e.g., target shape 210) and retrieves or otherwise identifies the global source code 330 for the source model (e.g., from global source codes 172 of FIG. 1) and the local part code 335 for each of its parts (e.g., from local part codes 174 of FIG. 1). For a given part of the source model, deformation module 300 (e.g., network input generator 146 of FIG. 1) generates network input 340 as a composite representation of target code 315, global source code 330, and local part code 335 (e.g., by concatenating the codes).

Network input 340 is fed into prediction network 345 to predict per-part deformation parameters 350 for a given part. In some embodiments, a predicted deformation is represented by components of a 3D translation (e.g., separate values for x, y and z translations) and/or components of a 3D resizing (e.g., separate values for resizing in x, y, and z dimensions). In an example implementation, a predicted translation component has a range of [−1,1] representing a fraction of the length of the unit diagonal of a given part's axis-aligned bounding box to translate the axis-aligned bounding box in a corresponding dimension. In another example implementation, a predicted resizing component has a range of [−1,1] representing the fraction of a length corresponding to the unit diagonal of a given part's axis-aligned bounding box to be added to a corresponding dimension of the part's axis-aligned bounding box. Generally, prediction network 345 is implemented using any suitable neural network. In an example implementation that outputs six deformation parameters per part (e.g., three translation and three resizing values), prediction network 345 is a lightweight 3-layer multilayer perceptron (MLP) network (e.g., with 512, 256, and 6 neurons).

As such, prediction network 345 predicts per-part deformation parameters 350 for each part in a source model. Part deformer 355 accesses source shape 320 and deforms each of its parts using the predicted deformation parameters for each part (e.g., by applying per-part translations and/or resizing). In some cases, prediction network 345 predicts deformation parameters for all the parts before part deformer 355 deforms the parts. In other cases, prediction network 345 predicts deformation parameters for, and part deformer 355 deforms, one or more parts at a time. The process is repeated for each part of the identified source model to obtain deformed shape 360 (e.g., a deformed 3D mesh, a deformed point cloud) that reproduces, matches, and/or approximates the shape and/or proportions of target shape 305.

### EXAMPLE TRAINING TECHNIQUES

In some embodiments, retrieval and deformation tool 131 includes separate networks for source retrieval (e.g., retrieval module 132) and source deformation (e.g., deformation module 140). In order to train these networks, a suitable training dataset is obtained. For example, in some embodiments in which retrieval and deformation tool 131 operates on a 3D point cloud, a training dataset that pairs partial or noisy input point clouds with corresponding ground truth 3D models is used. In in some embodiments in which retrieval and deformation tool 131 operates on a 2D image, a training dataset that pairs input images with corresponding ground truth 3D models is used.

In some embodiments, a retrieval module with one or more neural networks (e.g., retrieval module 132) and a deformation module one or more neural networks (e.g., deformation module 140) are jointly trained in an alternating fashion, keeping one module fixed when optimizing the other, and vice versa, in successive iterations. To train the deformation model, in some embodiments, a biased selection procedure is used to select an input source model to use with a paired input target and ground truth deformed model from a training dataset, and the selected input source model is used with the ground truth deformed model to train the deformation module. In an example implementation, the retrieval module is trained to learn a retrieval embedding space with a distance that is proportional to post-deformation fitting losses, and shapes with low fitting errors are represented nearby in the retrieval embedding space. Then, a source model is probabilistically sampled for a particular target using a probability that is weighted by distance between the source and target in the retrieval embedding space. As such, in this example, the deformation module is trained with a bias towards high probability source models and not random ones, ensuring the deformation module is aware of the retrieval module, and expanding the deformation module's capacity to learn to generate meaningful matches to a target shape.

In an example embodiment, the retrieval module embeds source models and a target into a retrieval embedding space R, and proximity in the retrieval embedding space is used to define a biased distribution that can be loosely interpreted as the probability of source model s being deformable to a target t:

[symbol]

(s,t)=p(s;t, [symbol] ,σ₀) (Eq. 2)

In an example embodiment,

$$p ( s ; t , \tilde{S} , \tilde{d} , \tilde{σ} ) = \frac{exp ( - {\tilde{d}}^{2} ( s , t ) / {\tilde{σ}}^{2} ( s ) )}{{\sum }_{{s}^{′} ∈ \tilde{S}} exp ( - {\tilde{d}}^{2} ( {s}^{′} , t ) / {\tilde{σ}}^{2} ( s ) )} \qquad ( Eq . 3 )$$

where d:(S×T)→ [symbol] is a distance function (e.g., the distance function given by equation 1) between a source model and a target, and \tilde{σ}: S→

[symbol]

is a potentially source-dependent scalar function. In an example implementation, σ₀(⋅) is a set constant (e.g., 100).

In an example implementation, for a given target from a training dataset, the probability P_{R} given by equation 2 is evaluated for each source model in a collection. Instead of choosing the highest-scoring source model, a soft retrieval is performed by probabilistically sampling K (e.g., 10) source models, where the probability of selecting a particular source model is given by the equation 2. In this example, K source models are retrieved from the distribution:

sᵢ˜ [symbol] (s,t), ∀i ϵ{1,2, . . . ,K} (Eq. 4)

In this example, the source models Sₜ={s₁, . . . , s_{K}} sampled via soft retrieval are used to train both the retrieval module to learn R and the deformation module to learn source-dependent deformation functions {Dₛ}. Adding randomness to the soft retrieval ensures that R is optimized with respect to both high-probability and low-probability instances, while biasing the training of the deformation module to encourage it to learn from the source models that the retrieval module is more likely to select.

In an example implementation, the retrieval and deformation modules are jointly trained by alternating between fixing one while optimizing the other, and vice versa. In some embodiments, the retrieval module and/or the deformation module are initialized by training on random pairs until convergence.

In some embodiments, to train the retrieval module with a given input target from a training dataset, the source models Sₜ={s, . . . , s_{K}} sampled via soft retrieval are deformed, and their post-deformation fitting losses (e.g. chamfer distance) to the target are computed:

d_{fit}(s,t)= [symbol] _{fit} [symbol] ₛ(t), tₜᵣᵤₑ) (Eq. 5)

In this implementation, the retrieval embedding space R is updated by penalizing the discrepancy between distances in the retrieval space dR and the post-deformation fitting losses Lfit using the probability measures (e.g., equations 2 or 3) estimated from the distances for the sampled source models:

$${ℒ}_{emb} = {\sum }_{k = 1}^{K} \vert p ( {s}_{k} , t , {S}_{t} , {d}_{ℛ} , {σ}_{0} ) - p ( {s}_{k} , t , {S}_{t} , {d}_{ℛ} , {σ}_{0} ) \vert \qquad ( Eq . 6 )$$

where d_{fit} is the post-deformation fitting loss and σₖ is a source-dependent scalar representing the range of deformability of each source model s ϵS. In some embodiments, σₖ is learned.

In some embodiments, to train the deformation module, the deformation functions {Dₛ_{ₖ}} for the K biased samples are updated by minimizing their post-deformation fitting losses, weighted by their soft probability measures (e.g., equations 2 or 3):

$${ℒ}_{def} = {\sum }_{k = 1}^{K} p ( {s}_{k} , t , {S}_{t} , {d}_{ℛ} , {σ}_{0} ) {ℒ}_{fit} ( {𝒟}_{{s}_{k}} ( t ) , t ) \qquad ( Eq . 7 )$$

This weighting scheme puts greater weight on source models that are closer to the target in the retrieval embedding space, thereby making the deformation module aware of the retrieval module and allowing the deformation module to specialize on more amenable source models with respect to the training target.

As such, in some embodiments, the retrieval and deformation modules are jointly trained to choose a source and deform it to fit a given target T, with respect to a fitting metric (e.g., chamfer distance).

### EXAMPLE FLOW DIAGRAMS

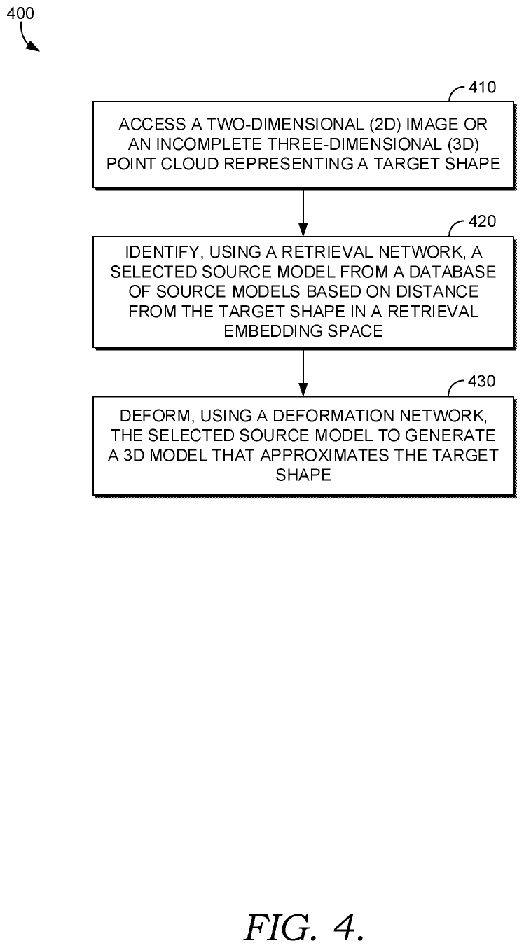

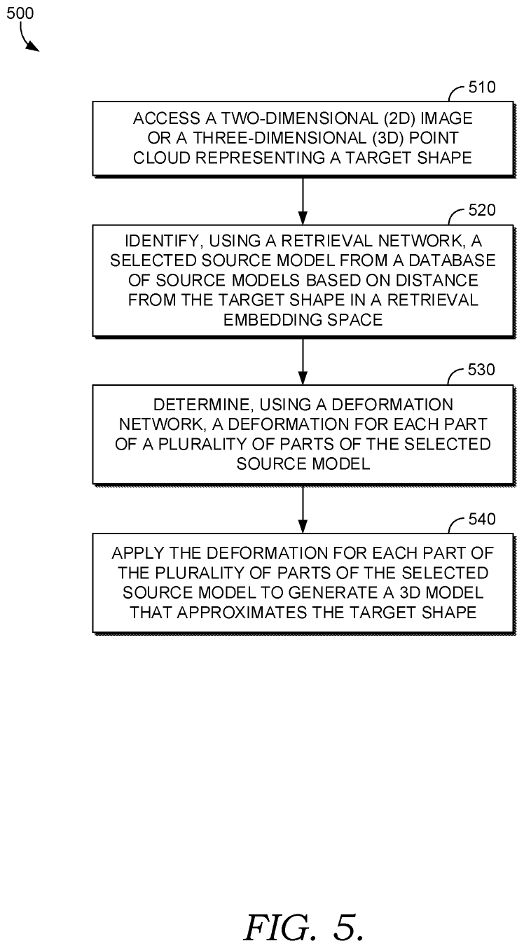

With reference now to FIGS. 4-5, flow diagrams are provided illustrating various methods generating a 3D model that approximates a target shape. Each block of the methods 400 and 500 and any other methods described herein comprise a computing process performed using any combination of hardware, firmware, and/or software. For instance, in some embodiments, various functions are carried out by a processor executing instructions stored in memory. In some cases, the methods are embodied as computer-usable instructions stored on computer storage media. In some implementations, the methods are provided by a standalone application, a service or hosted service (standalone or in combination with another hosted service), or a plug-in to another product, to name a few.

Turning initially to FIG. 4, FIG. 4 illustrates a method 400 for generating a 3D model that approximates a target shape, in accordance with embodiments described herein. Initially at block 410, a two-dimensional (2D) image or an incomplete three-dimensional (3D) point cloud representing a target shape is accessed. In an example implementation, a 2D image representing the target shape is uploaded to a retrieval and deformation tool. In another example, implementation, a 3D scan of a target shape is performed, resulting in a partial (e.g., noisy) 3D point cloud, and the partial 3D point cloud is uploaded to the retrieval and deformation tool. At block 420, a selected source model is identified from a database of source models, using a retrieval network, based on distance from the target shape in a retrieval embedding space. In an example implementation, the 2D image or the 3D point cloud is encode into a target code in the retrieval embedding space, and the selected source model is identified based on a function that quantifies distance between the target code and an area of the retrieval embedding space representing a range of potential deformations of the selected source model. At block 430, the selected source model is deformed using a deformation network to generate a 3D model that approximates the target shape.

Turning now to FIG. 5, FIG. 5 illustrates a method 500 for generating a 3D model that approximates a target shape by applying per-part deformations, in accordance with embodiments described herein. Initially at block 510, a two-dimensional (2D) image or a three-dimensional (3D) point cloud representing a target shape is accessed. At block 520, a selected source model is identified from a database of source models using a retrieval network based on distance from the target shape in a retrieval embedding space. At block 530, a deformation is determined for each part of a plurality of parts of the selected source model using a deformation network. At block 540, the deformation for each part of the plurality of parts of the selected source model is applied to generate a 3D model that approximates the target shape

### EXAMPLE OPERATING ENVIRONMENT

Having described an overview of embodiments of the present invention, an example operating environment in which some embodiments of the present invention are implemented is described below in order to provide a general context for various aspects of the present invention. Referring now to FIG. 6 in particular, an example operating environment for implementing embodiments of the present invention is shown and designated generally as computing device 600. Computing device 600 is but one example of a suitable computing environment and is not intended to suggest any limitation as to the scope of use or functionality of the invention. Neither should computing device 600 be interpreted as having any dependency or requirement relating to any one or combination of components illustrated.

In some embodiments, the present techniques are embodied in computer code or machine-useable instructions, including computer-executable instructions such as program modules, being executed by a computer or other machine, such as a cellular telephone, personal data assistant or other handheld device. Generally, program modules including routines, programs, objects, components, data structures, etc., refer to code that perform particular tasks or implement particular abstract data types. Various embodiments are practiced in a variety of system configurations, including hand-held devices, consumer electronics, general-purpose computers, more specialty computing devices, etc. Some implementations are practiced in distributed computing environments where tasks are performed by remote-processing devices that are linked through a communications network.

With reference to the example operating environment illustrated in FIG. 6, computing device 600 includes bus 610 that directly or indirectly couples the following devices: memory 612, one or more processors 614, one or more presentation components 616, input/output (I/O) ports 618, input/output components 620, and illustrative power supply 622. Bus 610 represents what may be one or more busses (such as an address bus, data bus, or combination thereof). Although the various blocks of FIG. 6 are shown with lines for the sake of clarity, in some cases, it is not possible to delineate clear boundaries for different components. In this case, metaphorically, the lines would be grey and fuzzy. As such, the diagram of FIG. 6 and other components described herein should be understood as merely illustrative of various example implementations, such as an example computing device implementing an embodiment or a portion thereof. Distinction is not made between such categories as “workstation,” “server,” “laptop,” “hand-held device,” etc., as all are contemplated within the scope of FIG. 6 and a “computing device.”

Computing device 600 typically includes a variety of computer-readable media. Computer-readable media can be any available media that can be accessed by computing device 600 and includes both volatile and nonvolatile media, and removable and non-removable media. By way of nonlimiting example, in some cases, computer-readable media comprises computer storage media and communication media. Computer storage media includes both volatile and nonvolatile, removable and non-removable media implemented in any method or technology for storage of information such as computer-readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by computing device 600. Computer storage media does not comprise signals per se. Communication media typically embodies computer-readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of any of the above should also be included within the scope of computer-readable media.

Memory 612 includes computer-storage media in the form of volatile and/or nonvolatile memory. In various embodiments, the memory is removable, non-removable, or a combination thereof. Example hardware devices include solid-state memory, hard drives, optical-disc drives, etc. Computing device 600 includes one or more processors that read data from various entities such as memory 612 or I/O components 620. Presentation component(s) 616 present data indications to a user or other device. Example presentation components include a display device, speaker, printing component, vibrating component, etc.

I/O ports 618 allow computing device 600 to be logically coupled to other devices including I/O components 620, some of which may be built in. Illustrative components include a microphone, joystick, game pad, satellite dish, scanner, printer, wireless device, etc. The I/O components 620 may provide a natural user interface (NUI) that processes air gestures, voice, or other physiological inputs generated by a user. In some instances, inputs are transmitted to an appropriate network element for further processing. In some embodiments, an NUI implements any combination of speech recognition, stylus recognition, facial recognition, biometric recognition, gesture recognition both on screen and adjacent to the screen, air gestures, head and eye tracking, and/or touch recognition (as described in more detail below) associated with a display of computing device 600. In some cases, computing device 600 is equipped with depth cameras, such as stereoscopic camera systems, infrared camera systems, RGB camera systems, touchscreen technology, and combinations of these, for gesture detection and recognition. Additionally or alternatively, the computing device 600 is equipped with accelerometers or gyroscopes that enable detection of motion, and in some cases, an output of the accelerometers or gyroscopes is provided to the display of computing device 600 to render immersive augmented reality or virtual reality.

Embodiments described herein support 3D model generation. The components described herein refer to integrated components of a 3D model generation system. The integrated components refer to the hardware architecture and software framework that support functionality using the 3D model generation system. The hardware architecture refers to physical components and interrelationships thereof and the software framework refers to software providing functionality that can be implemented with hardware embodied on a device.

In some embodiments, the end-to-end software-based system operates within the components of the 3D model generation system to operate computer hardware to provide system functionality. At a low level, hardware processors execute instructions selected from a machine language (also referred to as machine code or native) instruction set for a given processor. The processor recognizes the native instructions and performs corresponding low-level functions relating, for example, to logic, control and memory operations. In some cases, low-level software written in machine code provides more complex functionality to higher levels of software. As used herein, computer-executable instructions includes any software, including low-level software written in machine code, higher level software such as application software and any combination thereof. In this regard, system components can manage resources and provide services for the system functionality. Any other variations and combinations thereof are contemplated with embodiments of the present invention.

Some embodiments are described with respect a neural network, a type of machine-learning model that learns to approximate unknown functions by analyzing example (e.g., training) data at different levels of abstraction. Generally, neural networks model complex non-linear relationships by generating hidden vector outputs along a sequence of inputs. In some cases, a neural network includes a model of interconnected digital neurons that communicate and learn to approximate complex functions and generate outputs based on a plurality of inputs provided to the model. In various implementations, a neural network includes any of a variety of deep learning models, including convolutional neural networks, recurrent neural networks, deep neural networks, and deep stacking networks, to name a few examples. In some embodiments, a neural network includes or otherwise makes use of one or more machine learning algorithms to learn from training data. In other words, a neural network can include an algorithm that implements deep learning techniques such as machine learning to attempt to model high-level abstractions in data.

Although some implementations are described with respect to neural networks, some embodiments are implemented using other types of machine learning model(s), such as those using linear regression, logistic regression, decision trees, support vector machines (SVM), Naive Bayes, k-nearest neighbor (Knn), K means clustering, random forest, dimensionality reduction algorithms, gradient boosting algorithms, neural networks (e.g., auto-encoders, convolutional, recurrent, perceptrons, Long/Short Term Memory (LSTM), Hopfield, Boltzmann, deep belief, deconvolutional, generative adversarial, liquid state machine, etc.), and/or other types of machine learning models.

Having identified various components in the present disclosure, it should be understood that any number of components and arrangements may be employed to achieve the desired functionality within the scope of the present disclosure. For example, the components in the embodiments depicted in the figures are shown with lines for the sake of conceptual clarity. Other arrangements of these and other components may also be implemented. For example, although some components are depicted as single components, many of the elements described herein may be implemented as discrete or distributed components or in conjunction with other components, and in any suitable combination and location. Some elements may be omitted altogether. Moreover, various functions described herein as being performed by one or more entities may be carried out by hardware, firmware, and/or software, as described below. For instance, various functions may be carried out by a processor executing instructions stored in memory. As such, other arrangements and elements (e.g., machines, interfaces, functions, orders, and groupings of functions, etc.) can be used in addition to or instead of those shown.

The subject matter of the present invention is described with specificity herein to meet statutory requirements. However, the description itself is not intended to limit the scope of this patent. Rather, the inventor has contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

The present invention has been described in relation to particular embodiments, which are intended in all respects to be illustrative rather than restrictive. Alternative embodiments will become apparent to those of ordinary skill in the art to which the present invention pertains without departing from its scope.

From the foregoing, it will be seen that this invention is one well adapted to attain all the ends and objects set forth above, together with other advantages which are obvious and inherent to the system and method. It will be understood that certain features and subcombinations are of utility and may be employed without reference to other features and subcombinations. This is contemplated by and is within the scope of the claims.

What is claimed is:

1. One or more computer storage media storing computer-useable instructions that, when used by one or more computing devices, cause the one or more computing devices to perform operations comprising:
accessing a two-dimensional (2D) image or an incomplete three-dimensional (3D) point cloud representing a target shape;
identifying, using a retrieval network, a selected source model from a database of source models based on distance from the target shape in a retrieval embedding space; and
deforming, using a deformation network, the selected source model to generate a 3D model that approximates the target shape.

2. The one or more computer storage media of claim 1, the operations further comprising jointly training the retrieval network and the deformation network by alternately optimizing the retrieval network while keeping the deformation network fixed and optimizing the deformation network while keeping the retrieval network fixed.

3. The one or more computer storage media of claim 1, the operations further comprising jointly training the retrieval network and the deformation network to jointly learn the retrieval embedding space and an individual deformation space for each source model in the database.

4. The one or more computer storage media of claim 1, the operations further comprising jointly training the retrieval network and the deformation network to learn a deformation-aware retrieval embedding space as the retrieval embedding space and to learn a retrieval-aware deformation space.

5. The one or more computer storage media of claim 1, the operations further comprising:
identifying, based on an input target from a training dataset, a sampled source model from the database using the retrieval embedding space; and
training the retrieval network or the deformation network using the sampled source model as training data.

6. The one or more computer storage media of claim 1, the operations further comprising probabilistically sampling a training source model from the database of source models using a probability that is weighted by distance in the retrieval embedding space between the training source model and an input target from a training dataset.

7. The one or more computer storage media of claim 1, wherein deforming the selected source model comprises applying a source-specific deformation function that depends on a number of parts in the selected source model.

8. The one or more computer storage media of claim 1, wherein using the deformation network comprises:
predicting, by the deformation network, deformation parameters for a particular part of the selected source model based at least on a composite representation of the target shape, the selected source model, and the particular part; and
deforming the particular part using the deformation parameters.

9. A computerized method comprising:
receiving a two-dimensional (2D) image or a three-dimensional (3D) point cloud representing a target shape;
encoding, using a retrieval network, the 2D image or the 3D point cloud into a target code in a retrieval embedding space;
identifying a 3D source model from a database of 3D source models based on the target code and an area of the retrieval embedding space representing a range of potential deformations of the 3D source model; and
deforming, using a deformation network, the 3D source model to generate a 3D model that approximates the target shape.

10. The computerized method of claim 9, further comprising jointly training the retrieval network and the deformation network by alternately optimizing the retrieval network while keeping the deformation network fixed and optimizing the deformation network while keeping the retrieval network fixed.

11. The computerized method of claim 9, further comprising jointly training the retrieval network and the deformation network to jointly learn the retrieval embedding space and an individual deformation space for each 3D source model in the database.

12. The computerized method of claim 9, further comprising jointly training the retrieval network and the deformation network to learn a deformation-aware retrieval embedding space as the retrieval embedding space and to learn a retrieval-aware deformation space.

13. The computerized method of claim 9, further comprising:
identifying, based on an input target from a training dataset, a sampled 3D source model from the database using the retrieval embedding space; and
training the retrieval network or the deformation network using the sampled 3D source model as training data.

14. The computerized method of claim 9, further comprising probabilistically sampling a training 3D source model from the database using a probability that is weighted by distance in the retrieval embedding space between the training 3D source model and an input target from a training dataset.

15. The computerized method of claim 9, wherein deforming the 3D source model comprises applying a source-specific deformation function that depends on a number of parts in the 3D source model.

16. The computerized method of claim 9, wherein using the deformation network comprises:
predicting, by the deformation network, deformation parameters for a particular part of the 3D source model based at least on a composite representation of the target shape, the 3D source model, and the particular part; and
deforming the particular part using the deformation parameters.

17. A computer system comprising:
one or more hardware processors and memory configured to provide computer program instructions, that, when used by the one or more hardware processors, cause the one or more hardware processors to perform operations comprising:
accessing a two-dimensional (2D) image or a three-dimensional (3D) point cloud representing a target shape;
identifying, using a retrieval network, a selected source model from a database of source models based on distance from the target shape in a retrieval embedding space;
determining, using a deformation network, a deformation for each part of a plurality of parts of the selected source model; and
applying the deformation for each part of the plurality of parts of the selected source model to generate a 3D model that approximates the target shape.

18. The computer system of claim 17, the operations further comprising jointly training the retrieval network and the deformation network by alternately optimizing the retrieval network while keeping the deformation network fixed and optimizing the deformation network while keeping the retrieval network fixed.

19. The computer system of claim 17, the operations further comprising jointly training the retrieval network and the deformation network to jointly learn the retrieval embedding space and an individual deformation space for each source model in the database.

20. The computer system of claim 17, the operations further comprising jointly training the retrieval network and the deformation network to learn a deformation-aware retrieval embedding space as the retrieval embedding space and to learn a retrieval-aware deformation space.
